(19) United States
(12) Patent Application Publication
(10) Pub. No.: US 2012/0051873 A1
(43) Pub. Date: Mar. 1, 2012

(54) SUBSTRATE PROCESSING APPARATUS AND METHOD OF MANUFACTURING A SEMICONDUCTOR DEVICE

(75) Inventors: Koji SHIBATA, Toyama (JP); Tomoshi TANIYAMA, Toyama (JP); Takayuki NAKADA, Toyama (JP)

(73) Assignee: HITACHI KOKUSAI ELECTRIC INC., Tokyo (JP)

(21) Appl. No.: 13/180,079

(22) Filed: Jul. 11, 2011

(30) Foreign Application Priority Data
Sep. 1, 2010 (JP) 2010-195539

(51) Int. Cl. H01L 21/677

(52) U.S. Cl. 414/222.01; 414/804

(57) ABSTRACT

A substrate processing apparatus includes a substrate container holding shelf comprising a plurality of shelf boards configured to hold substrate containers thereon; a substrate container carrying mechanism configured to load and unload the substrate containers into/from the substrate container holding shelf; a substrate container holding shelf elevation mechanism configured to lift each of the plurality of the shelf boards of the substrate container holding shelf in a vertical direction; and a processing unit configured to receive at least one of the substrate containers from the substrate container holding shelf.

### CROSS-REFERENCE TO RELATED APPLICATIONS

This application is based upon and claims the benefit of priority from Japanese Patent Application No. 2010-195539, filed on Sep. 1, 2010, the entire contents of which are incorporated herein by reference.

### TECHNICAL FIELD

The present disclosure relates to a substrate processing apparatus for processing a substrate such as a semiconductor wafer and the like, and a method of manufacturing a semiconductor device.

### BACKGROUND

As an example of a substrate processing apparatus, there is known a vertical-type heat treatment apparatus having therein substrate containers, each of which accommodates a plurality of substrates. Generally in such a vertical-type heat treatment apparatus, substrate containers each accommodating a plurality of substrates are carried into the apparatus, so that, e.g., tens and hundreds of substrates are concurrently processed during one process treatment.

One configuration has been proposed where substrate containers are held on two holding shelves and then the two holding shelves are moved in a vertical direction through respective cylinders, thereby forming a space to be used as a carrying pathway for one of the substrate containers. Through such a carrying pathway, one of the substrate containers held on one holding shelf can be moved to be placed on the other holding shelf (for example, See Japanese Laid-Open Patent Application No. 2004-296996). Another configuration has been proposed that rotatable holding shelves, each of which accommodates plural sheets of substrates, are provided so as to load a sufficient number of substrate containers in a substrate processing apparatus (for example, See Japanese Laid-Open Patent Publication No. 2000-311935).

For example, the number of sheets of 450 mm wafers that can be processed in a vertical-type heat treatment apparatus may be set to be the same as the number of sheets of 300 mm wafers that can be processed in the vertical-type heat treatment apparatus. In this case, the number of containers required to hold 450 mm wafers is also set to be the same as the number of containers required to hold 300 mm wafers.

However, with the increase of wafer (substrate) diameter, e.g., from 300 mm to 450 mm, a dimension of a substrate container should also be increased. For example, a loading pitch (i.e., a pitch between two adjacent 450 mm wafers loaded) in a substrate container may be in the range of, e.g., 10 mm to 12 mm. Accordingly, if 25 sheets of 450 mm wafers are loaded in a substrate container, the height of the substrate container should be 50 mm or more higher than that of a substrate container accommodating the same number of 300 mm wafers. In addition, the weight of the substrate container accommodating 25 sheets of 450 mm wafers may be three times heavier or more than that of the substrate container accommodating the same number of 300 mm wafers. Further, if a rotatable holding shelf for use in a vertical-type heat treatment apparatus for processing 300 mm wafers may be employed in a vertical-type heat treatment apparatus for processing 450 mm wafers, the height of the vertical-type heat treatment apparatus (for processing a 450 mm wafer) may also be increased due to the increased size of the substrate containers. In this case, a weight of the substrate container itself is also increased, which requires an increase in the strength and solidity of a holding shelf configured to hold such a container. Further, a centrifugal force of the substrate container is increased when it is rotated by the holding shelf, which may cause an increase in the size of a driving unit and the complexity in the configuration of the apparatus.

Due to the above-described issues, the overall configuration of the vertical-type heat treatment apparatus to process 450 mm wafers is inevitably increased, which makes it difficult to process 450 mm wafers under the same dimensional requirements (such as the footprint of the apparatus, the height of the clean room, and the like) as the vertical-type heat treatment apparatus to process 300 mm wafers.

### SUMMARY

The present disclosure provides a substrate processing apparatus and a method of manufacturing a semiconductor device, which are capable of increasing the number of substrate containers to be held in the substrate processing apparatus while restraining an increase in the dimension of the substrate processing apparatus.

According to one aspect of the present disclosure, a substrate processing apparatus may include: a substrate container holding shelf including a plurality of shelf boards configured to hold substrate containers thereon; a substrate container carrying mechanism configured to load and unload the substrate containers into/from the substrate container holding shelf; a substrate container holding shelf elevation mechanism configured to lift each of the plurality of the shelf boards of the substrate container holding shelf in a vertical direction; and a processing unit configured to receive at least one of the substrate containers from the substrate container holding shelf

The substrate container holding shelf elevation mechanism may be configured to move a first shelf board of the shelf boards vertically, with the substrate container carrying mechanism being inserted into the first shelf board, by a first distance. The substrate container holding shelf elevation mechanism may be further configured to move a second shelf board located above the first shelf board vertically By a second distance greater than the first distance.

At least one of the shelf boards may be fixed in the substrate container holding shelf

At least two of the substrate containers may be arranged on two corresponding shelf boards of the substrate container holding shelf so that the at least two of the substrate containers are vertically aligned with each other to face a same direction.

According to another aspect of the present disclosure, a method of manufacturing a semiconductor device may include: loading and unloading substrate containers accommodating substrates into/from a substrate container holding shelf including a plurality of shelf boards using a substrate container carrying mechanism; moving a first shelf board of the substrate container holding shelf upward by a first distance, into which the substrate container carrying mechanism is inserted, using a holding shelf elevation mechanism; moving a second shelf board, which is located above the first shelf board, upward by a second distance greater than the first distance; taking out the substrates from the substrate containers; loading the substrates into a processing furnace; and processing the substrates in the processing furnace.

### BRIEF DESCRIPTION OF THE DRAWINGS

FIG. 1 is a perspective view showing a substrate processing apparatus in accordance with the present disclosure.

FIG. 2 is a side cross-sectional view showing the substrate processing in accordance with the present disclosure.

FIG. 3 is a schematic diagram showing a configuration of a controller of the substrate processing apparatus in accordance with the present disclosure.

FIG. 4 is a flowchart showing operations of the controller of the substrate processing apparatus in accordance with the present disclosure.

FIG. 5A, FIG. 5B, and FIG. 5C are diagrams for explaining operations of the substrate processing apparatus in accordance with the present disclosure.

FIG. 6A, FIG. 6B, and FIG. 6C are diagrams for explaining operations of the substrate processing apparatus in accordance with the present disclosure.

FIG. 7A, FIG. 7B, and FIG. 7C are diagrams for explaining operations of the substrate processing apparatus in accordance with the present disclosure.

### DETAILED DESCRIPTION

With reference to the accompanying drawings, embodiments of the present disclosure will now be described.

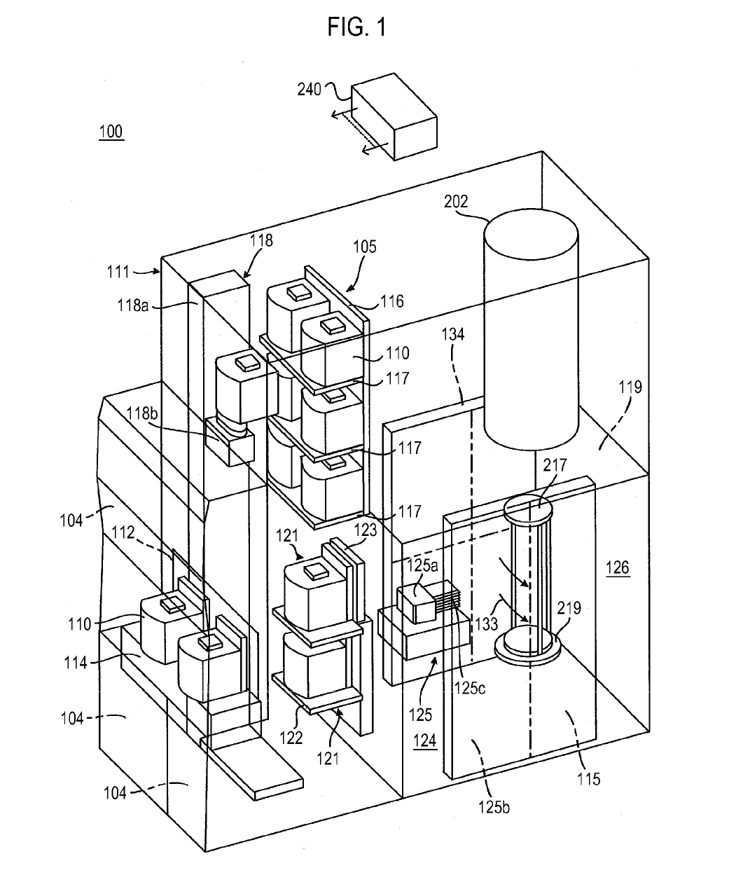

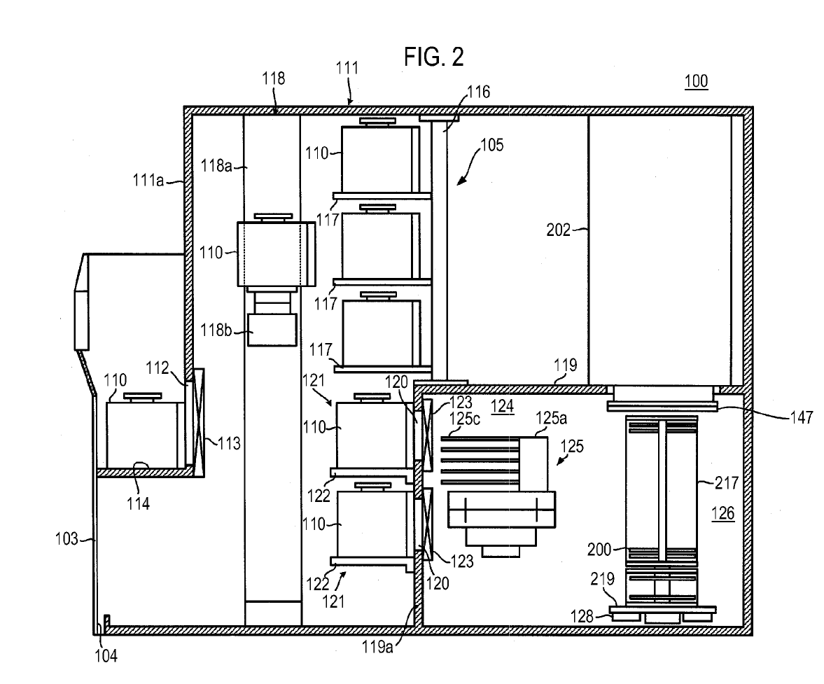

In accordance with one embodiment of the present disclosure, a substrate processing apparatus is configured as, e.g., a semiconductor manufacturing apparatus that performs a method of manufacturing an integrated circuit (IC). Also, as one example of the substrate processing apparatus, the following is a description of a vertical-type processing apparatus (hereinafter, simply referred to as a processing apparatus) that performs oxidization, a diffusion treatment, a chemical vapor deposition (CVD) treatment, and the like on a substrate. FIG. 1 shows a perspective view of a substrate processing apparatus in accordance with the present disclosure. Also, FIG. 2 shows a side cross-sectional view of the substrate processing apparatus shown in FIG. 1.

As shown in FIGS. 1 and 2, a housing 111 is provided in a substrate processing apparatus 100 including a hoop (hereinafter, referred to as a pod) 110 as a wafer carrier configured to accommodate a plurality of wafers (substrates) 200 made of silicon and the like.

A front maintenance opening 103 serving as an opening part, which is provided to allow maintenance therethrough, is formed on a front part of a front wall 111a of the housing 111. Front maintenance doors 104 are provided to open and close the front maintenance opening 103.

A pod load/unload opening 112 is formed on the front wall 111a of the housing 111 to provide communication between the inside of housing 11 and the outside of housing 111. The pod load/unload opening 112 is configured to be opened and closed by a front shutter 113.

A load port 114 is disposed at a front side of the pod load/unload opening 112. The load port 114 is configured to place pods 110 thereon so that the pods 110 are aligned thereto. The pods 110 are placed on the load port 114 and unloaded therefrom by an in-process carrying device (not shown).

A pod shelf (substrate container holding shelf) 105 is disposed in an upper part of an approximately central region horizontally extending from a front side of the housing to a rear side thereof inside the housing 111. The pod shelf 105 is provided with a support member 116 that is disposed along a vertical direction and with multi-stage shelf boards 117 that are supported by the support member 116 so that they are independently movable in a vertical direction at upper, middle, and lower positions with respect to the support member 116. The multi-stage shelf boards 117 of the pod shelf 105 are configured to place and hold the pods 110 on the respective stages. For example, the pod shelf 105 is configured to arrange and hold a plurality of the pods 110 on the corresponding multi-stage shelf boards 117 in a vertical direction so that the arranged pods face in the same direction along the vertical direction.

A pod carrying device (substrate container carrying device) 118 is disposed between the load port 114 and the pod shelf 105 inside the housing 111. The pod carrying device 118 is configured with a pod elevator 118a serving as a shaft part configured to move upward and downward in a vertical direction while holding the pods 110. Further, the pod carrying device 118 includes a pod carrying unit 118b, which serves as a carrying mechanism, configured to place thereon the pods 110 to transfer them in a horizontal direction. The pod carrying device 118 is configured to transfer the pods 110 among the load pod 114, the pod shelf 105, and a pod opener 121 through continuous operation of the pod elevator 118a and the pod carrying unit 118b.

In a lower part of the approximately central region extending from the front side to the rear side of the housing 111, a sub-housing 119 is provided in a rear side of the housing 111. A pair of wafer load/unload openings 120 are arranged at upper and lower locations in a vertical direction on a front wall 119a of the sub-housing 119 to load and unload wafers 200 into/from the sub-housing 119. The pair of wafer load/unload openings 120 are provided with a corresponding pair of pod openers 121. Each of the pod openers 121 is provided with a placing table 122 for placing thereon the pod 110, and a cap attaching/detaching mechanism 123 for attaching and detaching a cap of the pod 110, the cap being used as a sealing member. The pod opener 121 is configured to open and close a wafer loading/unloading opening of the pod 110 by attaching and detaching the cap of the pod 110 placed on the placing table 122 through the cap attaching/detaching mechanism 123.

The sub-housing 119 defines a carrying chamber 124 that is fluidically isolated from a space where the pod carrying device 118 and the pod shelf 105 are installed. A wafer carrying mechanism 125 is disposed at a front region of the carrying chamber 124. The wafer carrying mechanism 125 includes a wafer carrying device 125a configured to rotate or linearly carry a wafer in a horizontal direction, and a wafer carrying device elevator 125b configured to move the wafer carrying device 125a upward and downward. As schematically shown in FIG. 1, the wafer carrying device elevator 125b is disposed between a right part of the housing (pressure-resistant housing) 111 and a right part of the front region of the carrying chamber 124 of the sub-housing 119. By a continuous operation of the wafer carrying device elevator 125b and the wafer carrying device 125a, the wafers 200 are loaded on (in a charging operation) and unloaded from (in a discharging operation) a boat (substrate holder) 217 by using tweezers (substrate holding members) 125c of the wafer carrying device 125a used as a placing unit of the wafers 200.

A waiting station 126 configured to accommodate the boat 217 waiting for processing is provided in a rear region of the carrying chamber 124. A processing furnace 202 is provided above the waiting station 126. A lower end of the processing furnace 202 is configured to be opened and closed by a furnace opening shutter 147.

As schematically shown in FIG. 1, a boat elevator 115 configured to move the boat 217 upward and downward is disposed between a right end part of the housing (pressure-resistant housing) 111 and a right end part of the waiting station 126 of the sub-housing 119. A sealing cap 219 serving as a cover is horizontally disposed on an arm 128 serving as a coupling member that is coupled to a platform of the boat elevator 115. The sealing cap 219 is configured to vertically support the boat 217 to thereby close the lower end part of the processing furnace 202.

The boat 217 is provided with a plurality of holding members. The plurality of holding members of the boat 217 are configured to horizontally hold a plurality of wafers 200 (for example, 50 to 125 sheets of wafers 200), respectively, so that the wafers 200 are concentrically aligned along a vertical direction.

As schematically shown in FIG. 1, a clean unit 134, which is configured with a supply fan for supplying clean air 133 (e.g., a cleaned atmosphere or an inert gas) and a dust-proof filter, is provided in a left part of the carrying chamber 124 opposite another part of the carrying chamber 124 in which the wafer carrying device elevator 125b and the boat elevator 115 are provided. A notch alignment device (not shown) serving as a substrate alignment device for aligning positions of the wafers 200 in a circumferential direction is disposed between the wafer carrying device 125a and the clean unit 134.

The clean air 133 blown out of the clean unit 134 is flown to the notch alignment device, the wafer carrying device 125a, and the boat 217 in the waiting station 126 and then is absorbed by a duct (not shown) to be exhausted outside the housing 111 or to be circulated to a first side (supply side) which is an absorbing side of the clean unit 134 so that the clean air 133 is blown out into the carrying chamber 124 again by the clean unit 134.

Now, operations of the substrate processing apparatus 100 will be described in detail.

In the following description, operations of respective components of the substrate processing apparatus 100 are controlled by a controller 240.

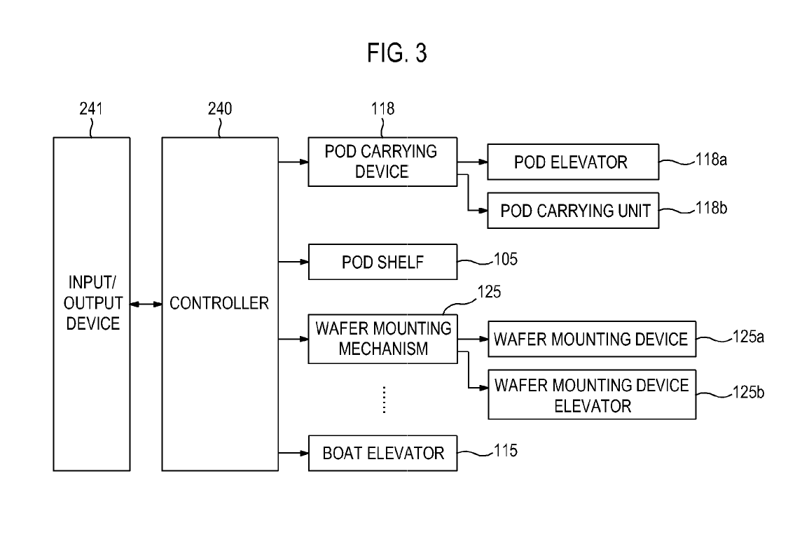

FIG. 3 illustrates a configuration of the controller 240. The controller 240 is configured to control the pod carrying device 118, the pod shelf 105, the wafer carrying mechanism 125, and the boat elevator 115 through an input/output device 241.

As show in FIGS. 1 and 2, the pod load/unload opening 112 is opened by the front shutter 113 when the pod 110 is placed on the load port 114. Thereafter, the pod 110 placed on the load port 114 is loaded into the housing 111 from the pod load/unload opening 112 by the pod carrying device 118.

The loaded pod 110 is automatically carried to a designated shelf board 117 of the pod shelf 105 by the pod carrying device 118 to be temporarily held thereon. Then, the pod 110 is unloaded from the pod shelf 105 to one of the pod openers 121 to be temporarily stored therein. In this manner, the pod 110 is unloaded from the pod shelf 105 to one of the pod openers 121 to be mounted on the placing table 122. Alternatively, the pod 110 may be directly carried to the pod opener 121 to be mounted on the placing table 122. In this case, the wafer load/unload opening 120 of the pod opener 121 is closed by the cap attaching/detaching mechanism 123. Also, the clean air 133 flows through the carrying chamber 124 so that the carrying chamber 124 is filled with the clean air 133. For example, by filling the carrying chamber 124 with nitrogen gas as the clean air 133, the carrying chamber 124 is set to have an oxygen concentration of 20 ppm or less which is significantly lower than the oxygen concentration of the inside (atmospheric air) of the housing 111.

An opening side end face of the pod 110 mounted on the placing table 122 is pressed against a periphery section of the wafer load/unload opening 120 at the front wall 119a of the sub-housing 119. Then, the cap of the pod 110 is detached by the cap attaching/detaching mechanism 123 to open the wafer load/unload opening 120.

When the pod 110 is opened by the pod opener 121, the wafers 200 are picked-up from the pod 110 through the wafer load/unload opening 120 by the tweezers 125c of the wafer carrying device 125a. Thereafter, the wafers 200 are aligned in the notch alignment device (not shown) and loaded into the waiting station 126 disposed in the rear part of the carrying chamber 124 to be loaded on (or charged to) the boat 217. The wafer carrying device 125a, after delivering the wafers 200 to the boat 217, returns to the pod 110 so as to load subsequent wafers 200 to the boat 217.

While performing the loading operation of the wafers 200 to the boat 217 by the wafer carrying mechanism 125 in one (e.g., the upper stage) of the pod openers 121, another pod 110 is carried to and mounted on one of the other (e.g., the lower stage) pod openers 121 from the pod shelf 105 by the pod carrying device 118. As such, the opening operations of the two pods 110 can be concurrently performed by the pod openers 121.

If the predetermined number of wafers 200 are loaded to the boat 217, the lower portion of the processing furnace 202 closed by the furnace opening shutter 147 is then opened by the furnace opening shutter 147. Subsequently, the sealing cap 219 is lifted upward by the boat elevator 115 such that the boat 217 accommodating the group of the wafers 200 is carried (or loaded) into the processing furnace 202.

After the loading operation is completed, predetermined processes are performed on the group of wafers 200 in the processing furnace 202.

Once the predetermined processes are completed, the wafers 200 and the pods 110 are taken out from the housing 111 according to a sequence of operations which is reverse to the above-described operations, except for the wafer alignment in the notch alignment device (not shown).

The following is a description of operations relating to an elevation mechanism (substrate container elevation mechanism) of the pod carrying device 118 and the pod shelf 105 of the substrate processing apparatus 100 in accordance with one embodiment of the present disclosure. In the following, an example configuration will be described where the pod 110 placed on an n-th shelf board 117 (where n is an integer selected in the range of 1 to M, i.e., a total number of shelf boards 117 in the pod shelf 105) is unloaded from the pod shelf 105 so that the pod 110 is temporarily stored on the pod shelf 105 and then is carried to the pod opener 121.

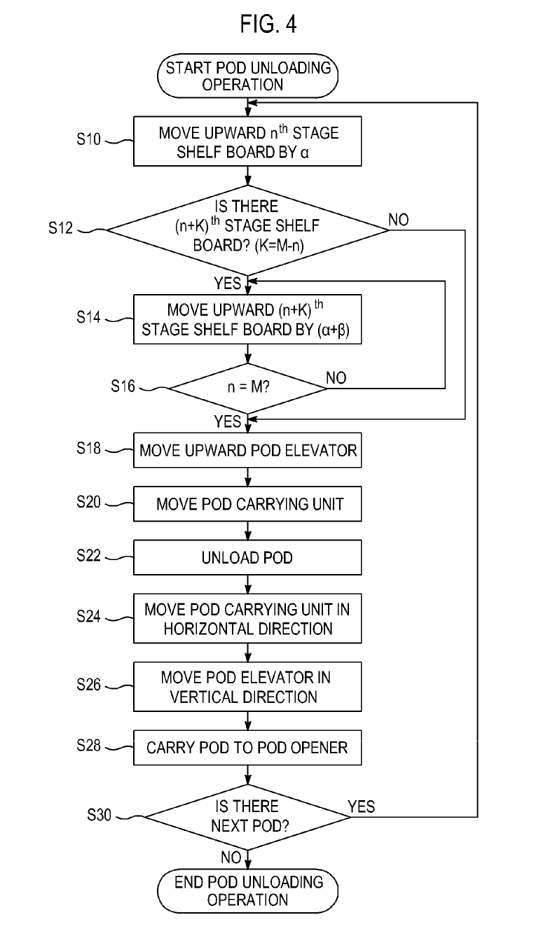

FIG. 4 illustrates a flowchart showing operations of carrying the pod 110 which are controlled by the controller 240.

At step S10, the n-th shelf board 117 holding thereon the pod 110 (which is to be unloaded therefrom) is lifted by a distance α. Herein, the distance a may be set to a proper value to thereby form a sufficient space, through which the pod carrying unit 118b is inserted into the n-th self board 117 of the pod shelf 105 without being interfered with (or contacting) the pod opener 121 and another pod 110 placed on a lower shelf board 117.

Subsequently, at step S12, it is determined whether an (n+K)-th shelf board 117 exists above the n-th shelf board 117, wherein K=M−n. If it is determined that the (n+K)-th shelf board 117 exists, the process goes to step S14. Otherwise, if it is determined that the (n+K)-th shelf board 117 does not exist, the process goes to step S18.

At step S14, the (n+K)-th shelf board 117 is lifted upward by a distance (α+β). Herein, a distance β may be set to a proper value to thereby form a space, through which the pod carrying unit 118b can lift the pod 110 from the n-th shelf board 117 (i.e., the pod 110 is unloaded without being interfered with by a upper shelf board 117).

At step S16, it is determined whether n is equal to M (i.e., n=M). If it is determined that n is not equal to M, n is incremented (i.e., n=n+1) and the process returns to step S14. Otherwise, if it is determined that n is equal to M, the process goes to step S18. Herein, n=M represents that the pod 110 has been unloaded from the uppermost shelf of the shelf boards 117.

At step S18, the pod elevator 118a is lifted in a vertical direction so that the pod carrying unit 118b is moved upward to reach below (e.g., a position horizontally corresponding to) the n-th shelf board 117.

Subsequently, at step S20, the pod carrying unit 118b is moved in a horizontal direction to be positioned below the lower end of a pod 110 to be subsequently unloaded (i.e., inserted between the bottom of the pod 110 and the upper surface of the n-th self board 117).

At step S22, the pod 110 (to be subsequently unloaded) is unloaded from the n-th shelf board 117 by an operation of the pod carrying unit 118b.

At step S24, the pod carrying unit 118b is moved in a horizontal direction to reach a position corresponding to the pod opener 121 (i.e., a position aligned with the pod opener 121 (which is located below or above the position) along a vertical direction).

At step S26, the pod elevator 118a is moved in a vertical direction to reach a position corresponding to the pod opener 121.

Thereafter, at step S28, the pod 110 is carried to the pod opener 121.

At step S30, it is determined whether another pod 110 to be subsequently carried remains in the pod shelf 105. If it is determined that the pod shelf 105 holds such a pod 110 to be subsequently carried, the process returns to step S10. Otherwise, if it is determined that there is no more pod 110 to be carried, the entire process is completed.

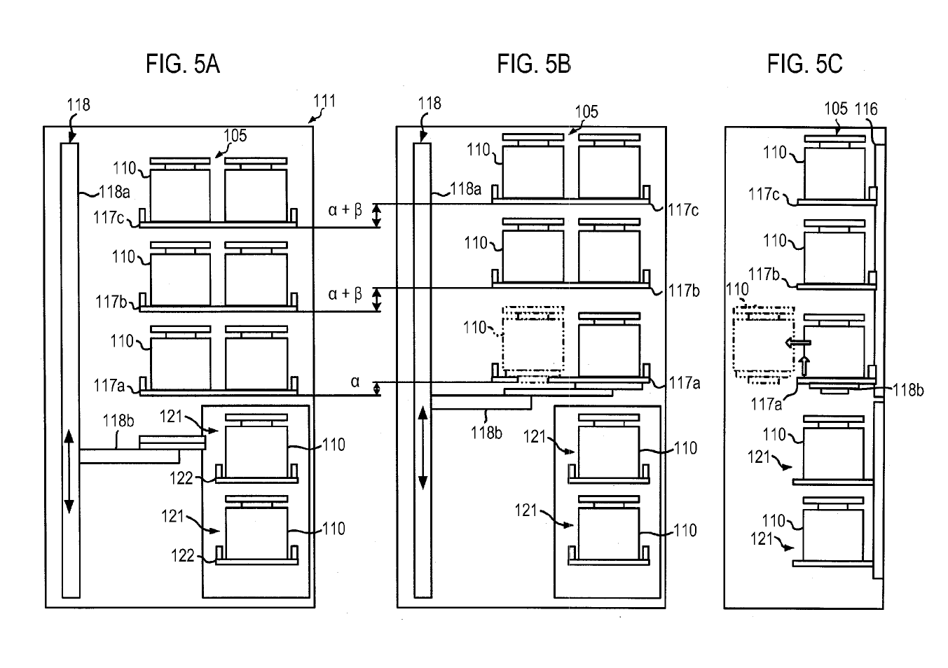

With reference to FIGS. 5A to 5C, FIGS. 6A to 6C, FIGS. 7A to 7C, the following is a description of operations relating to an elevation mechanism (substrate container elevation mechanism) of the pod carrying device 118 and the pod shelf 105 of the substrate processing apparatus 100 in accordance with one embodiment of the present disclosure by way of illustrative examples.

The following examples will be described with respect to the pod shelf 105 in which the pods 110 are arranged in two columns on three stages of shelf boards. Also, the shelf boards 117 of the pod shelf 105 for placing the pods 110 thereon are sequentially referred to as a first stage shelf board 117a, a second stage shelf board 117b, and a third stage shelf board 117c, respectively, according to its vertical locations from the bottom to the top of the pod shelf 105.

Referring to FIGS. 5A to 5C, there is shown an illustrative example when n=1 (for the example described above with reference to FIG. 4), i.e., the pod 110 is unloaded from the first stage shelf board 117a. FIG. 5A is a front view of the pod shelf 105 and shows a lifting (or elevation) operation in the pod shelf 105. Also, FIGS. 5B and 5C show a front view and a side view of the pod shelf 105, respectively, when unloading one of the pods 110 held in the pod shelf 105.

Initially, the first stage shelf board 117a of the pod shelf 105 is lifted by the distance a in a vertical direction (step S10 of FIG. 4). Subsequently, the second stage shelf board 117b and the third stage shelf board 117c, which are located above the first stage shelf board 117a, are lifted by the distance (α+β) in a vertical direction (steps S12, S14, and S16 of FIG. 4). In this way, a sufficient space is formed, through which the pod carrying unit 118b can be inserted to unload the pod 110 placed on the first stage shelf board 117a without causing any interference with another pod 110 placed on the pod opener 121. Further, it is possible to prevent the unloading of the pod 110 (from the first stage shelf board 117a) from being interfered with by the upper stage shelf board 117, e.g., the second stage shelf board 117b holding thereon another pod 110.

Afterward, the pod carrying unit 118b is moved upward in a vertical direction to reach the lower end of the first stage shelf board 117a by the operation of the pod elevator 118a of the pod carrying device 118 (step S18 of FIG. 4). Subsequently, the pod carrying unit 118b is moved in a horizontal direction to reach the bottom of the pod 110 to be unloaded (i.e., so that the pod carrying unit 118b is inserted between the upper surface of the first stage shelf board 117a and the bottom surface of the pod 110) (step S20 of FIG. 4). The pod 110 is unloaded from the first stage shelf board 117a by the operations of the pod elevator 118a and the pod carrying unit 118b (step S22 of FIG. 4). Continuously, through the operations of the pod carrying unit 118b and the pod elevator 118a (steps S24 and S26 of FIG. 4), the pod 110 is carried to the pod opener 121 (step S28 of FIG. 4).

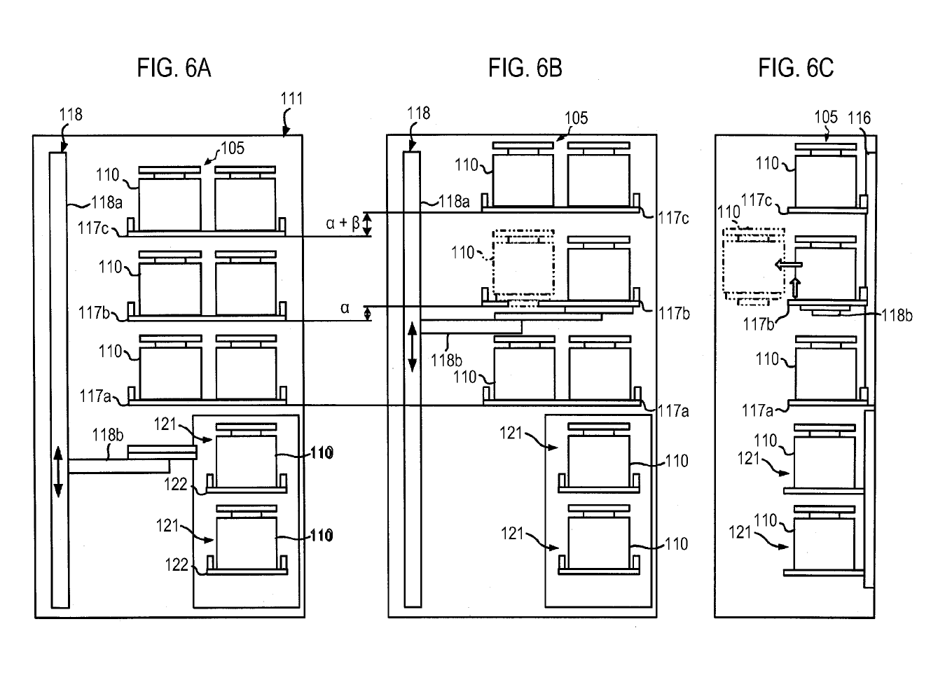

Referring to FIGS. 6A to 6C, there is shown an illustrative example of when n=2 (for the example described above with reference to FIG. 4), i.e., the pod 110 is unloaded from the second stage shelf board 117b. FIG. 6A is a front view of the pod shelf 105 and shows a lifting (or elevation) operation in the pod shelf 105. Also, FIG. 6B and FIG. 6C show a front view and a side view of the pod shelf 105, respectively, when unloading one of the pods 110 held in the pod shelf 105.

Initially, the second stage shelf board 117b of the pod shelf 105 is lifted by the distance a in a vertical direction (step S10 of FIG. 4). Subsequently, the third stage shelf board 117c, which is located above the second stage shelf board 117b, is lifted by the distance (α+β) in a vertical direction (steps S12, S14, and S16 of FIG. 4). In this way, a sufficient space is formed, through which the pod carrying unit 118b can be inserted to unload the pod 110 placed on the second stage shelf board 117b without causing any interference with another pod 110 placed on the first stage shelf board 117a. Further, it is possible to prevent the unloading of the pod 110 (from the second stage shelf board 117b) from being interfered with by the upper stage shelf board, i.e., the third stage shelf board 117c.

Afterward, the pod carrying unit 118b is moved upward in a vertical direction to reach the lower end of the second stage shelf board 117b by the operation of the pod elevator 118a of the pod carrying device 118 (step S18 of FIG. 4). Subsequently, the pod carrying unit 118b is moved in a horizontal direction to reach the bottom of the pod 110 to be unloaded (i.e., so that the pod carrying unit 118b is inserted between the upper surface of the second stage shelf board 117b and the bottom surface of the pod 110) (step S20 of FIG. 4). The pod 110 is unloaded from the second stage shelf board 117b by the operations of the pod elevator 118a and the pod carrying unit 118b (step S22 of FIG. 4). Continuously, through the operations of the pod carrying unit 118b and the pod elevator 118a (steps S24 and S26 of FIG. 4), the pod 110 is carried to the pod opener 121 (step S28 of FIG. 4).

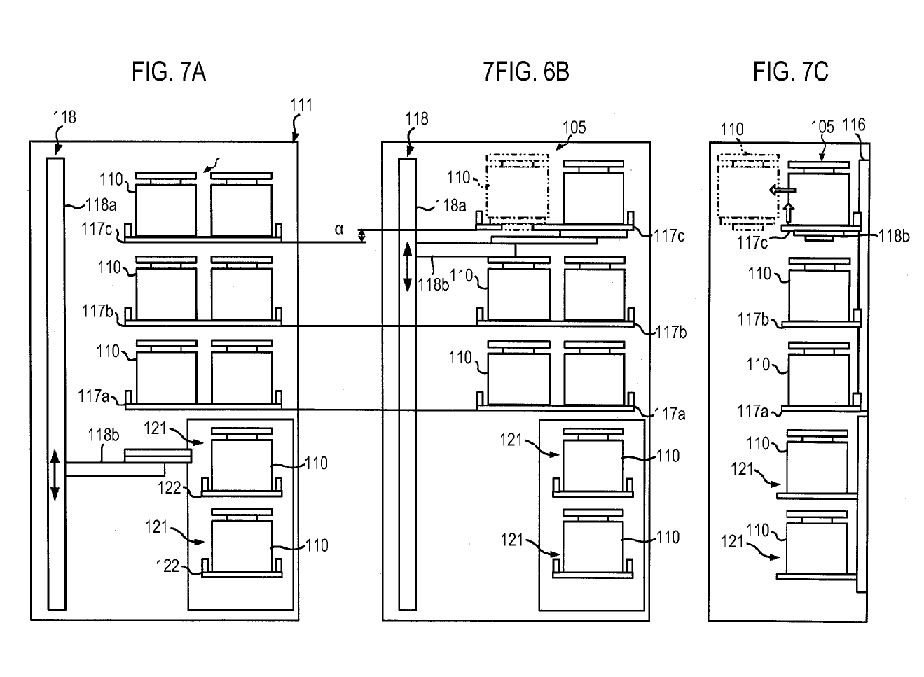

Referring to FIGS. 7A to 7C, there is shown an illustrative example of when n=3 (for the example described above with reference to FIG. 4), i.e., the pod 110 is unloaded from the third stage shelf board 117c. FIG. 7A is a front view of the pod shelf 105 and shows a lifting operation in the pod shelf 105. Also, FIG. 7B and FIG. 7C show a front view and a side view of the pod shelf 105, respectively, when unloading the pod 110 one of the pods 110 held in the pod shelf 105.

Initially, the third stage shelf board 117c of the pod shelf 105 is lifted by the distance a in a vertical direction (step S10 of FIG. 4). Since the third stage shelf board 117c is the uppermost shelf board in the pod shelf 105, the process goes to step S18.

Afterward, the pod carrying unit 118b is moved upward in a vertical direction to reach the lower end of the third stage shelf board 117c by the operation of the pod elevator 118a of the pod carrying device 118 (step S18 of FIG. 4). Subsequently, the pod carrying unit 118b is moved in a horizontal direction to reach the bottom of the pod 110 to be unloaded (i.e., so that the pod carrying unit 118b is inserted between the upper surface of the third stage shelf board 117c and the bottom surface of the pod 110) by the operation of the pod carrying unit 118b (step S20 of FIG. 4). The pod 110 is unloaded from the third stage shelf board 117c by the operations of the pod elevator 118a and the pod carrying unit 118b (step S22 of FIG. 4). Continuously, through the operations of the pod carrying unit 118b and the pod elevator 118a (steps S24 and S26 of FIG. 4), the pod 110 is carried to the pod opener 121 (step S28 of FIG. 4). In this way, a sufficient space is formed, through which the pod carrying unit 118b can be inserted to unload the pod 110 placed on the third stage shelf board 117c without causing any interference with another pod 110 placed on the second stage shelf board 117b. For sake of unloading the pod 110 from the third stage shelf board 117c (i.e., the upper most stage shelf board), a ceiling of the housing 111 is disposed at a sufficient height so as to cause no interference with the unloading operation, and thus the pod 110 placed on the third stage shelf board 117c can be unloaded without any interference with other components in the housing 111.

As described above, the pod carrying unit 118b is inserted to reach the lower end of the pod 110 by sequentially moving upward the respective shelf boards 117a, 117b, and 117c of the pod shelf 105 and operating the pod elevator 118a. As a result, the vertical movement of the pod shelf 105 can be decreased. Further, a space (or carrying passage) required for unloading the pod 110 is sufficiently secured while reducing a pitch between the shelf boards 117. Consequently, the overall height of the substrate processing apparatus can be maintained at a desired level.

In the above examples, in the operation of the elevation mechanism (holding shelf elevation mechanism) of the pod shelf 105, the pod 110 is temporarily stored on the pod shelf 105 and then is carried to the pod opener 121. Further, the above examples of the elevation mechanism describe that the pod 110 is unloaded from the pod shelf 105, but the present disclosure is not limited thereto. Alternatively, in some embodiments, the elevation mechanism may be applicable when the pod 110 is loaded into the pod shelf 105 from the load port 114.

Further, in some embodiments, the shelf boards 117 may be configured with a combination of fixed-type boards and elevation-type boards. By decreasing the number of fixed-type shelf boards 117, a height of the substrate processing apparatus can also be reduced. Therefore, by configuring the shelf boards 117 with a proper combination of fixed type and elevation-type boards depending on any requirements of the apparatus height, the dimensions of the apparatus can be optimized. Further, since an elevation mechanism is not required for the fixed-type shelf boards 117, the number of components associated with the elevation mechanism can be reduced.

In the above examples, the pods 110 are arranged in the pod shelf 105 in two columns, for each of which one elevation mechanism is provided, but it is not limited thereto. Alternatively, in some embodiments, elevation mechanisms may be provided for the respective pods 110. In this way, various operations can be realized.

As described above, according to the present disclosure, there are provided a substrate processing apparatus and a method of manufacturing a semiconductor device, which are capable of increasing the number of substrate containers to be held in the substrate processing apparatus while restraining an increase in the dimensions of the substrate processing apparatus.

While certain embodiments have been described, these embodiments have been presented by way of example only, and are not intended to limit the scope of the disclosures. Indeed, the novel embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a substrate container holding shelf comprising a plurality of shelf boards configured to hold substrate containers thereon;
a substrate container carrying mechanism configured to load and unload the substrate containers into/from the substrate container holding shelf;
a substrate container holding shelf elevation mechanism configured to lift each of the plurality of the shelf boards of the substrate container holding shelf in a vertical direction; and
a processing unit configured to receive at least one of the substrate containers from the substrate container holding shelf.

2. The apparatus of claim 1, wherein the substrate container holding shelf elevation mechanism is configured to move a first shelf board of the shelf boards vertically by a first distance, with the substrate container carrying mechanism being inserted into the first shelf board.

3. The apparatus of claim 2, where the substrate container holding shelf elevation mechanism is further configured to move a second shelf board of the shelf boards, located above the first shelf board, vertically by a second distance greater than the first distance.

4. The apparatus of claim 1, wherein at least one of the shelf boards is fixed in the substrate container holding shelf.

5. The apparatus of claim 1, wherein at least two of the substrate containers are arranged on two corresponding shelf boards of the substrate container holding shelf so that the at least two of the substrate containers are vertically aligned with each other to face a same direction.

6. A method of manufacturing a semiconductor device, the method comprising:
loading and unloading substrate containers accommodating substrates into/from a substrate container holding shelf comprising a plurality of shelf boards using a substrate container carrying mechanism;
moving a first shelf board of the substrate container holding shelf upward by a first distance, into which the substrate container carrying mechanism is inserted, using a holding shelf elevation mechanism;
moving a second shelf board, which is located above the first shelf board, upward by a second distance greater than the first distance;
taking out the substrates from the substrate containers;
loading the substrates into a processing furnace; and
processing the substrates in the processing furnace.
